(19) United States
(12) Patent Application Publication
(10) Pub. No.: US 2013/0058059 A1
(43) Pub. Date: Mar. 7, 2013

(54) ELECTROMAGNETIC WAVE SHIELDING CASE

(71) Applicants: Myoung Ki Min, Gunpo (KR); Chang-Seak Jung, Gwangmyeong (KR)

(72) Inventors: Myoung Ki Min, Gunpo (KR); Chang-Seak Jung, Gwangmyeong (KR)

(73) Assignees: HYUNDAI MOTOR COMPANY, Seoul (KR); OMRON AUTOMOTIVE ELECTRONIC KOREA CO., LTD., Anseong (KR); KIA MOTORS CORPORATION, Seoul (KR)

(21) Appl. No.: 13/314,917

(22) Filed: Dec. 8, 2011

(30) Foreign Application Priority Data
Sep. 1, 2011 (KR) 10-2011-0088466

(51) Int. Cl. H05K 5/02

(52) U.S. Cl. 361/756; 361/752

(57) ABSTRACT

Disclosed is an electromagnetic wave shielding case. More particularly, an electromagnetic wave shielding case for a circuit board provided with a connector includes an upper case configured to cover an upper portion of the circuit board, and a lower case configured to form an internal space when the upper case is connected therewith, wherein the circuit board is attached to an upper surface of the lower case. A shield configured to shield electromagnetic waves, is attached to the circuit board within the internal space formed by the upper case and the lower case to shield components (both inside the case and out) from electromagnetic waves.

### CROSS-REFERENCE TO RELATED APPLICATION

This application claims priority to and the benefit of Korean Patent Application No. 10-2011-0088466 filed in the Korean Intellectual Property Office on Sep. 1, 2011, the entire contents of which are incorporated herein by reference.

### BACKGROUND OF THE INVENTION

(a) Field of the Invention

The present invention relates to an electromagnetic wave shielding case. More particularly, the present invention relates to an electromagnetic wave shielding case for shielding electromagnetic waves efficiently from a circuit board.

(b) Description of the Related Art

Conventionally, metal material or special paint has been used for manufacturing cases that shields electromagnetic waves from coming in contact with various components. However, when metal material is used for manufacturing a whole case, costs and weight are increased and in some case make its manufacture prohibitive. On the other hand, when special paint is used on the surface of the case, the weight may be reduced, but the shielding efficiency is not sufficient compared to when the metal material is used as the shielding component.

The above information disclosed in this Background section is only for enhancement of understanding of the background of the invention.

### SUMMARY OF THE INVENTION

The present invention has been made in an effort to provide an electromagnetic wave shielding case having advantages of reducing cost and weight with increased shielding electromagnetic wave efficiency.

In the exemplary embodiment of the present invention, an electromagnetic wave shielding case for a circuit board is provided with a connector according to an exemplary embodiment of the present invention may include an upper case configured to cover an upper portion of the circuit board, a lower case which forms an internal space where the upper case and the circuit board are attached thereto by connecting with the upper case, and a shield for shielding electromagnetic waves, wherein the shield is disposed on the circuit board within the internal space.

The illustrative embodiment of the present invention may also include a connector accommodating portion, which accommodates the connector, may be formed to the upper case. At least one of fixing groove may be formed in the circuit board. Furthermore, a fixing protrusion may correspond to the fixing groove and may be formed as part of the shield. Additionally, the shield may be attached to the circuit board by inserting the fixing protrusion into the fixing groove.

The upper case and the lower case may be formed of plastic material, and the shield may be formed of metal material that shields electromagnetic waves. A lower portion of the shield may have an opening or space which can receive and cover one or more electrical components on the circuit board.

In some embodiments, the shield may cover at least part or some of the electrical components to shield those covered components from electromagnetic waves radiated from other portions of the electrical components or other electrical components.

The upper case may be monolithically formed together with the shield through an insert injection molding process. The shield may be formed to be smaller than the upper case. Also in some embodiments the upper case may be monolithically formed together with the shield through an insert injection molding process in order for the shield to be positioned at predetermined position at all time. Alternatively, however, the shield and the upper case may also be formed separately as two distinct structures.

As described above, an electromagnetic wave shielding case according to an exemplary embodiment of the present invention may be only partially formed of metal material to reduce costs and weight. By implementing the above device, partial shielding of electromagnetic waves is possible and thus electromagnetic waves are efficiently shielded between electrical components as well as outside and within the case. Also when the shield is made of metal material is integrally formed with the case made of plastic and manufacturing process may be simplified and enhance shielding efficiency of electromagnetic waves is realized.

### BRIEF DESCRIPTION OF THE DRAWINGS

The above and other objects and features of the present invention will become apparent from the following description of embodiments given in conjunction with the accompanying drawings, in which:

FIG. 1 is an exploded perspective view of an electromagnetic wave shielding case according to an exemplary embodiment of the present invention.

FIG. 2 is a perspective view of an electromagnetic wave shielding case according to an exemplary embodiment of the present invention.

FIG. 3 is a cross-sectional view along line III-III of FIG. 2.

### DESCRIPTION OF SYMBOLS

10: shield
15: fixing protrusion
20: upper case
23: engage hole
27: connector accommodating portion
30: lower case
33: engage protrusion
40: circuit board
45: fixing groove
47: connector
50: internal space

### DETAILED DESCRIPTION OF THE EMBODIMENTS

An exemplary embodiment of the present invention will hereinafter be described in detail with reference to the accompanying drawings.

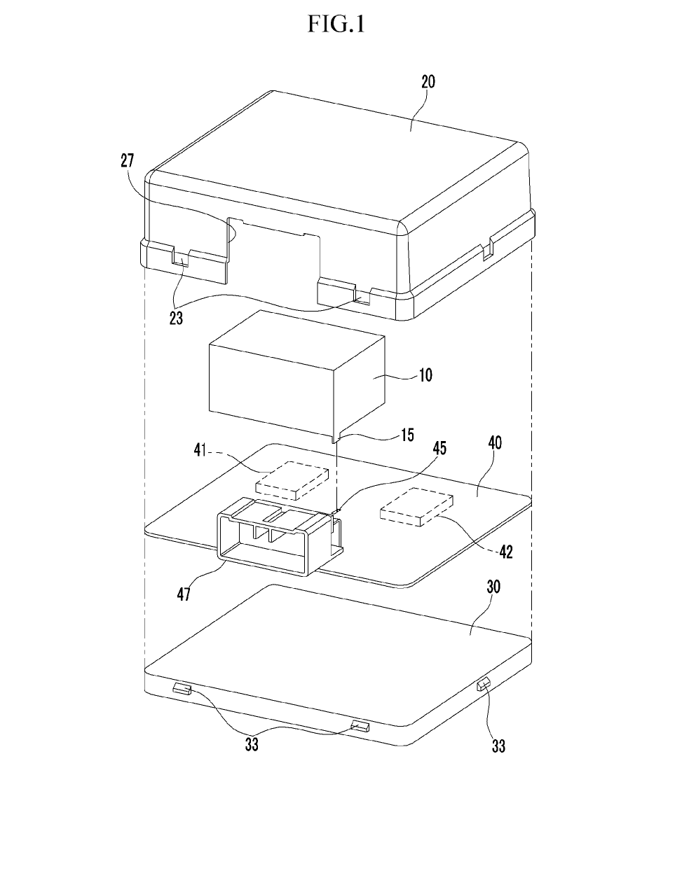

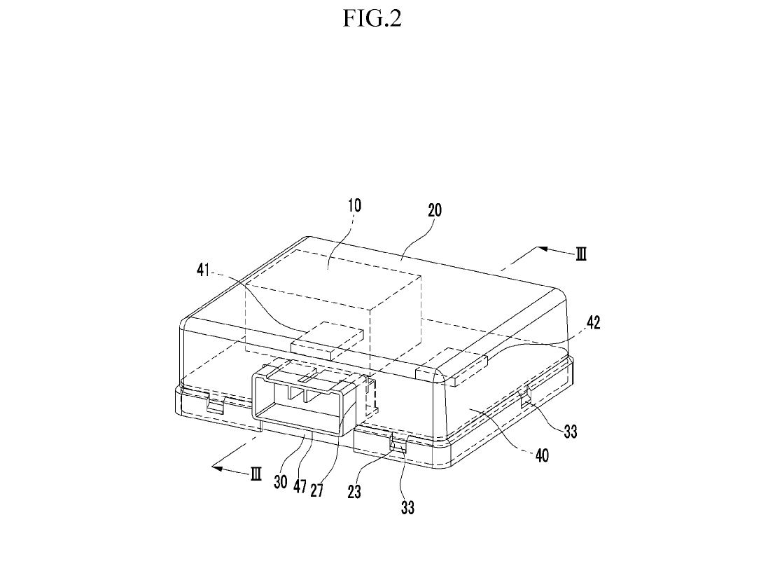

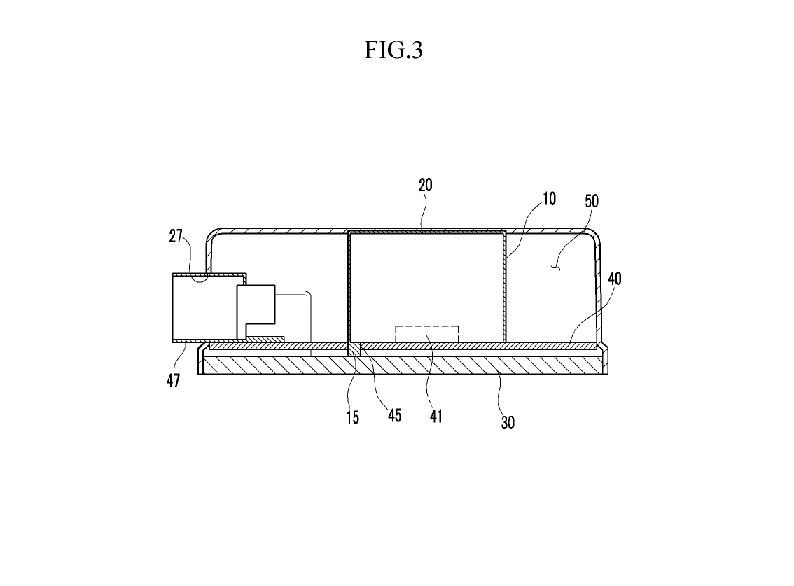

FIG. 1 and FIG. 2 are an exploded perspective view and perspective view of an electromagnetic wave shielding case according to an exemplary embodiment of the present invention respectively and FIG. 3 is a cross-sectional view along line III-III of FIG. 2.

Referring to FIGS. 1-3, an electromagnetic wave shielding case according to an exemplary embodiment of the present invention includes a circuit board 40, a shield 10, an upper case 20 and a lower case 30. The circuit board 40 may be, for example, a printed circuit board of which a copper sheet is laminated thereon and electrical components 41 and 42 (e.g., an integrated circuit, a resister, a switch and so on) are disposed thereon. A connector 47 is disposed on and attached to the circuit board 40. The connector 47 may be attached via any means of attaching non-electrical components to a circuit board. For example, the connector 47 may be attached via adhesion or mechanical connectors known in the art.

The connector 47 may be protrudedly installed on one side of the circuit board 40 for being connected to other electronic devices or a power supply. The fixing groove 45 is formed in the circuit board 40 and may penetrate the surface of the circuit board 40 accordingly to receive the connector 47.

The shield 10 may be made of metal for shielding electromagnetic waves radiated from the circuit board 40. In the FIG. 1, the shield 10 is drawn as hexahedron shape but it is not limited thereto.

The shield 10 may have a size which is formed proportionally to cover only selected components 41 of the electrical components 41 and 42 on the circuit board 40. Referring to FIG. 3, a lower portion of the shield 10 is open on one end to receive and enclose or cover the electrical components 41.

A fixing protrusion 15 is formed as part of the shield 10. The fixing protrusion 15 is inserted into a fixing groove 45, formed in the circuit board 40, to fix the shield 10 to the circuit board 40 and hold it in place.

The upper case 20 covers upper portion of the circuit board 40. In the FIG. 1, the upper case 20 is drawn as hexahedron shape of which a lower portion thereof is opened to receive and cover the shield 10 the printed circuit 40 and all of its components and the top surface of the lower case 30, but it is not limited thereto.

The upper case 20 includes an engagable aperture 23 and a connector accommodating aperture 27. The engagable aperture 23 and the connector accommodating aperture 27 may be formed on one side of the upper case 20. The connector accommodating portion 27 is configured to receive and surround the connector 47 while at the same time enclosing and covering the upper surface of the circuit board 40 and the shield case 10.

The lower case 30 supports a lower portion of the circuit board 40 and is connected with the upper case 20 via the engagable apertures 23 and protrusions 33. In the FIG. 1, the lower case 30 is a flat plate having predetermined thickness, but it is not limited thereto.

The lower case 30 includes an engagable protrusion 33 and the engagable protrusion 33 may be formed to a side of the lower case 30. The upper case 20 and the lower case 30 are assembled by engaging the engagable protrusion 33 and the engagable aperture 23.

The upper case 20 and the lower case 30 may be made of a plastic material in order to further reduce weight and costs associated with the manufacture thereof. Referring to FIG. 3, an internal space 50 is formed by assembling of the upper case 20 and the lower case 30, and the circuit board 40 and the shield 10 are disposed within the internal space 50 of the combined cased formed by the upper and lower cases.

In the FIG. 1, each constituent element of the electromagnetic wave shielding case is drawn as separated components. However the upper case 20 and the shield 10 may be integrally formed in some embodiments to further reduce costs associated with its manufacture. That is, the upper case 20 made of plastic is integrally formed with the shield 10 made of metal for shielding the electromagnetic waves through an insert injection molding process. In the insert injection molding process, the shield 10 is fixed and plastic material is injected for integrally forming the above described combined component. In the insert injection molding process, the shield 10 is positioned at a predetermined position of the upper case 20, and the fixing groove 45 is formed in the circuit board 40 corresponding to the position of the shield 10.

As shown in FIG. 2, when the electromagnetic wave shielding case is assembled, and the lower case 30 fills in the opening in the lower portion of the upper case 20, the circuit board 40, the shield 10 and a part of the connector 47 are disposed within the assembled case 20 and 30 and the other part of the connector 47 is protruded from the assembled case 20 and 30.

As described above, the shield 10 may cover only selected component(s) 41 of the electrical components 41 and 42 on the circuit board 40, and thus the shield 10 may shield the electromagnetic waves radiated from the selected component(s) 41.

As shown in FIG. 3, the shield 10 may be disposed between the upper case 20 and the circuit board 40 without any gap therebetween. That is, the height of the shield 10 may be the same as distance between the upper case 20 and the circuit board 40 within the assembled case 20 and 30.

In FIG. 3, since the shield 10 and the upper case 20 may be integrally formed through insert injection molding, the upper portion of the shield 10 may be slightly inserted into the upper portion of the upper case 20. In this case, the insert injection molding may use injection molding in an insert molding process, which combines multiple combinations of materials for example, different kind of plastics, metal and plastic, ceramics and plastics and so on into a single unit.

As described above, the electromagnetic wave shielding case according to the exemplary embodiment of the present invention may be assembled from the cases 20 and 30 made of plastic material and/or partially metal and thus cost and weight may be reduced accordingly. Since partial shielding of the electromagnetic waves is possible shielding of electromagnetic waves may be realized while at the same time reducing costs and weight. Furthermore, because the shield may be made of a metal material integrally formed with the case made of plastic, the manufacturing process may be simplified, thus enhancing shielding efficiency of the electromagnetic waves.

While this invention has been described in connection with what is presently considered to be practical exemplary embodiments, it is to be understood that the invention is not limited to the disclosed embodiments. On the contrary, it is intended to cover various modifications and equivalent arrangements included within the spirit and scope of the appended claims.

What is claimed is:

1. An electromagnetic wave shielding case for a circuit board provided with a connector, the electromagnetic wave shielding case comprising:
an upper case configured to cover an upper portion of the circuit board;
a lower case configured to form an internal space when the upper case is connected therewith, wherein the circuit board is attached to an upper surface of the lower case; and
a shield configured to shield electromagnetic waves, wherein the shield is attached to the circuit board within the internal space formed by the upper case and the lower case.

2. The electromagnetic wave shielding case of claim 1, wherein a connector accommodating aperture configured to receive the connector, and formed on one side of the upper case.

3. The electromagnetic wave shielding case of claim 1, further comprising at least one fixing groove formed in the circuit board, and a fixing protrusion corresponding to the fixing groove formed as part of the shield, wherein the shield is attached to the circuit board by inserting the fixing protrusion into the fixing groove.

4. The electromagnetic wave shielding case of claim 1, wherein the upper case and the lower case are formed of a plastic material.

5. The electromagnetic wave shielding case of claim 1, wherein the shield is formed of a metal material for shielding electromagnetic waves.

6. The electromagnetic wave shielding case of claim 1, wherein a lower portion of the shield forms an opening for receiving and enclosing electrical components on the circuit board.

7. The electromagnetic wave shielding case of claim 6, wherein the shield encloses a portion of the electrical components to shield electromagnetic waves radiated from the enclosed portion of the electrical components.

8. The electromagnetic wave shielding case of claim 1, wherein the upper case is monolithically formed together with the shield via an insert injection molding process.

9. The electromagnetic wave shielding case of claim 8, wherein the shield is formed to be smaller than the upper case and the upper case is monolithically formed together with the shield through the insert injection molding process to position the shield at predetermined position consistently.

10. A case for shielding one or more components from electromagnetic waves, the case comprising:
a first case configured to cover a circuit board;
a second case configured to support the printed circuit board and attach to the first case to thereby enclose the printed circuit board; and
a shield case configured to shield one or more components both inside the case and outside the case from electromagnetic waves, wherein the shield is integrally formed with the first case and is made of a different material than the first case.

11. The case of claim 10, wherein an aperture is formed on one side of the first case and is configured to receive the connector.

12. The case of claim 10, further comprising at least one groove formed in the circuit board, and a protrusion corresponding to the groove formed as part of the shield, wherein the shield is attached to the circuit board by inserting the protrusion into the groove.

13. The case of claim 10, wherein the first case and the second case are formed of a plastic material.

14. The case of claim 10, wherein the shield is formed of a metal material for shielding electromagnetic waves.

15. The case of claim 11, wherein a lower portion of the shield forms an opening for receiving and enclosing electrical components on the circuit board.

16. The case of claim 15, wherein the shield encloses a portion of the electrical components to shield electromagnetic waves radiated from the enclosed portion of the electrical components.

17. The case of claim 11, wherein the first case is monolithically formed together with the shield via an insert injection molding process.

18. The case of claim 19, wherein the shield is formed to be smaller than the first case and the first case is monolithically formed together with the shield to position the shield at predetermined position consistently
